(19) United States
(12) Patent Application Publication
(10) Pub. No.: US 2016/0189916 A1
(43) Pub. Date: Jun. 30, 2016

(54) SCANNING CHARGED PARTICLE BEAM DEVICE HAVING AN ABERRATION CORRECTION APERTURE AND METHOD OF OPERATING THEREOF

(71) Applicant: Applied Materials Israel Ltd., Rehovot (IL)

(72) Inventors: Jürgen Frosien, Riemerling (DE); Stefan Lanio, Erding (DE); Ady Arie, Herzeliya (IL); Roy Shiloh, Tel Aviv (IL); Roei Remez, Tel Aviv (IL)

(21) Appl. No.: 14/972,651

(22) Filed: Dec. 17, 2015

Related U.S. Application Data
(60) Provisional application No. 62/093,065, filed on Dec. 17, 2014.

(51) Int. Cl. H01J 37/147; H01J 37/28

(52) U.S. Cl. CPC H01J 37/1474; H01J 37/28

(57) ABSTRACT

A scanning charged particle beam apparatus is described. The scanning charged particle beam apparatus includes a charged particle beam source configured for generating a primary charged particle beam; an objective lens configured for forming a probe on a specimen; a scanning deflection assembly configured for scanning the probe over a surface of the specimen; and an aberration correction aperture, wherein the aberration correction aperture includes an aperture body having a transparent aperture portion configured for having the primary charged particle beam pass through the transparent aperture portion; and a membrane portion including a solid material, wherein the membrane portion is provided at the transparent aperture portion and wherein the membrane portion is configured for having the primary charged particle beam pass through the solid material, wherein the membrane portion has a varying thickness.

The present application claims priority to U.S. Application No. 62/093,065, filed Dec. 17, 2014, the entire contents of which are incorporated by reference herein for all purposes.

### TECHNICAL FIELD

Embodiments of the present disclosure relate to aberration correction apertures. Embodiments of the disclosure particularly relate to aberration correction elements introducing a phase shift correction of aberrations, particularly spherical aberration. Typically, embodiments relate to scanning charged particle beam apparatuses and methods of operating scanning charged particle beam apparatuses.

### BACKGROUND

Charged particle beam systems are widely spread in the semiconductor industry. Examples of charged particle beam devices are electron microscopes such as secondary electron microscopes (SEM), electron beam pattern generators, ion microscopes as well as ion beam pattern generators. Charged particle beams, in particular electron beams, offer superior spatial resolution compared to photon beams, due to their short wavelengths at comparable particle energy.

In charged particle beam systems, for example probe forming systems like SEMs, aberrations are a limiting factor for the optical performance, particularly the achievable resolution. For example, a diameter of a probe is determined by the demagnification of the source, the source size, and axial aberrations such as chromatic aberrations and spherical aberrations.

For high resolution low-voltage SEMs, the minimum probe size is mainly determined by an optimization between diffraction and chromatic aberration. Accordingly, low energy width electron sources and/or utilization of a monochromators can improve the resolution. Utilizing at reduced energy width allows for larger aperture angles, which shifts the optimum trade-off between diffraction and chromatic aberration towards a small electron probe diameter. This results in an increasing aperture angle and increasing spherical aberrations, which may then also limit the achievable resolution.

In high current SEM systems, like systems for electron beam inspection (EBI) moderate spot diameters are advantageous. However, the need for increasing probe current inside the electron probe is a boundary condition due to electron-electron-interaction. Accordingly, EBI optics are also limited by spherical aberrations because a wider electron beam allows for a higher beam current, a reduced current density, or both.

A plurality of correctors for chromatic aberrations and/or spherical aberrations has been discussed. For example, multipole correctors or mirror correctors have been theoretically calculated. Only a few corrected SEMs have been built so far and are mainly used in an R&D (research and development) environment. SEMs, which are used in a production environment, for example for CD (critical dimensioning), DR (defect review), or EBI (electron beam inspection), beneficially have a high robustness. The above-mentioned correctors have a high complexity and sensitivity, which limits the robustness. In light of the above, it is beneficial to provide improved correctors, particularly correctors for spherical aberrations, charged particle beam systems having such improved correctors, particularly CD systems, DR systems, and EBI systems, and method of operating thereof.

### SUMMARY

According to one embodiment, a scanning charged particle beam apparatus is provided. The scanning charged particle beam apparatus includes a charged particle beam source configured for generating a primary charged particle beam; an objective lens configured for forming a probe on a specimen; a scanning deflection assembly configured for scanning the probe over a surface of the specimen; and an aberration correction aperture, wherein the aberration correction aperture includes an aperture body having a transparent aperture portion configured for having the primary charged particle beam pass through the transparent aperture portion; and a membrane portion including a solid material, wherein the membrane portion is provided at the transparent aperture portion and wherein the membrane portion is configured for having the primary charged particle beam pass through the solid material, wherein the membrane portion has a varying thickness.

According to another embodiment, a method of operating a scanning charged particle beam apparatus is provided the method includes generating a primary charged particle beam; and correcting aberrations of the primary charged particle beam with an aberration correction aperture, wherein at least a portion of the primary charged particle beam passes through a membrane portion of the aberration correction aperture for introducing a phase shift within the primary charged particle beam.

According to another embodiment, a scanning charged particle beam apparatus is provided. The scanning charged particle beam apparatus includes a charged particle beam source configured for generating a primary charged particle beam; an objective lens configured for forming a probe on a specimen; a scanning deflection assembly configured for scanning the probe over a surface of the specimen; and an aberration correction aperture, including an aperture body having a transparent aperture portion configured for having the primary charged particle beam pass through the transparent aperture portion; and a membrane portion including a solid material, wherein the membrane portion is provided at the transparent aperture portion and wherein the membrane portion is configured for having the primary charged particle beam pass through the solid material, wherein the membrane portion has a varying thickness. The scanning charged particle beam apparatus further includes a spray aperture, which is positioned downstream along the primary charged particle beam of the aberration correction aperture, wherein the spray aperture is configured for blocking charged particles scattered from the aberration correction aperture. For example, as an optional modification thereof, a spray aperture can be provided downstream of an element selected from the group consisting of: a monochromator, an electrostatic deflector, a magnetic deflector, a combined magnet electrostatic deflector, e.g. a Wien filter, and combinations thereof.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic drawing of a scanning charged particle beam device including an aberration correction aperture according to embodiments described herein;

FIGS. 2A to 2D show schematic drawings of aberration correction apertures according to embodiments described herein;

FIGS. 3 and 4 show schematic drawings of aberration correction apertures according to yet further embodiments described herein;

FIGS. 5A to 5D show schematic drawings of membrane portions, which can be used in aberration correction apertures according to embodiments described herein;

FIGS. 6 to 9A show schematic drawings of scanning charged particle beam devices including aberration correction apertures according to embodiments described herein;

FIG. 9B shows a schematic drawing of an aberration correction aperture according to yet further embodiments described herein; and

FIG. 10 shows a flowchart of a method of operating a scanning charged particle beam device according to embodiments described herein.

### DETAILED DESCRIPTION

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

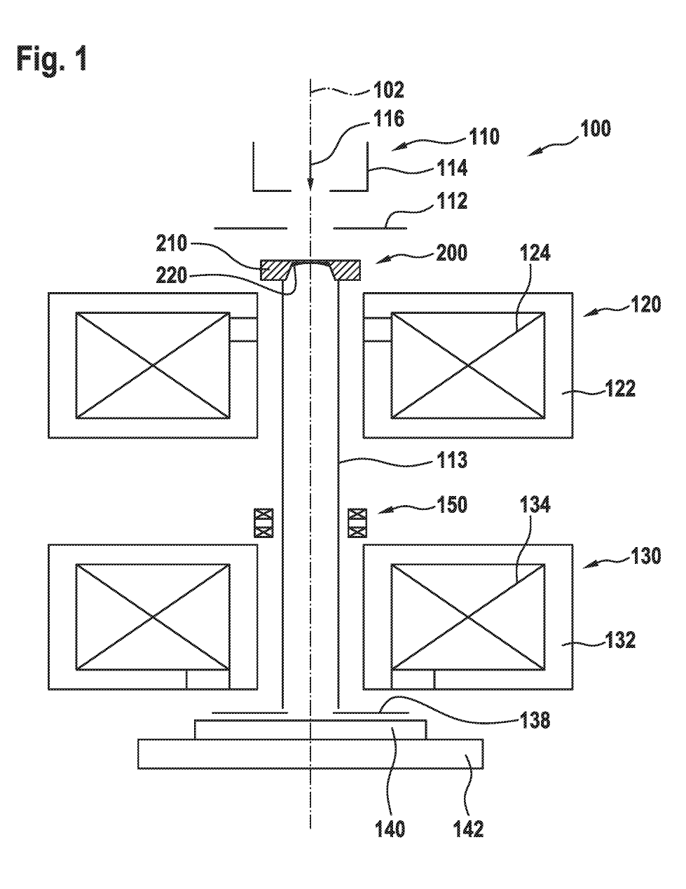

FIG. 1 shows the scanning charged particle beam apparatus 100. A charged particle beam source 110 generates a primary charged particle beam. The primary charged particle beam is guided in the scanning charged particle beam apparatus 100 and is focused on a specimen 140 by objective lens 130. According to some embodiments, the objective lens 130 images the tip of the emitter 116 or its virtual source on the specimen 140, wherein the probe is generated, i.e. the objective lens is configured for forming a probe on the specimen. A scanning deflection assembly 150 scans the probe over the surface or surface area of the specimen 140. The scanning deflection assembly can be a 1-stage, 2-stage or even higher stage deflector arrangement. According to various embodiments magnetic, electrostatic or combined electrostatic-magnetic deflectors can be provided in the scanning deflection assembly. By scanning the probe over the surface of the specimen, an image can be generated. Accordingly, embodiments described herein relate to scanning electron microscopes (SEM), scanning transmission electron microscopes (STEM), focused ion beam systems (FIB), or other scanning charged particle beam apparatuses, wherein a probe, i.e. a fine probe, such as a probe defining the resolution of the apparatus, is scanned over a surface of the specimen to be imaged. A scanning electron microscope can for example be an SEM for critical dimensioning (CD), defect review (DR), or inspection (EBI, that is electron beam inspection).

In scanning charged particle beam systems or scanning charged particle beam apparatuses, aberrations are one limiting factor for the optical performance, in particular the resolution. The size of the probe, which mainly determines the resolution, is not only defined by the magnification of the source and the size of the source, but also by axial aberrations, for example chromatic and spherical operations. Particularly for low voltage SEMs having for example the landing energy of the electrons on the specimen of 50 eV to 5 keV, for example 300 eV or below, previous improvements allow for using larger aperture angles. Accordingly, a further probe size reduction may have an increasing influence on spherical operations. In high-energy SEMs chromatic aberrations are as such of smaller relevance and spherical aberration correction is beneficial. Also high current systems, like systems for electron beam inspection (EBI), which have for example moderate spot diameters in the range of 5 nm to 100 nm, the resolution of the scanning charged particle beam apparatus is limited by spherical operations to a significant amount. Accordingly, correction of spherical aberrations is beneficial.

Embodiments described herein provide an improved aberration correction including an aberration correction aperture 200 (see FIG. 1). As compared to previous attempts using multipole correctors or mirror correctors, including an aberration correction aperture in a scanning charged particle beam device provides a configuration with reduced complexity, reduced sensitivity of adjustment, and increased robustness, so that SEMs, which are used in a production environment, for example for CD (critical dimensioning), DR (defect review), or EBI (electron beam inspection) can also benefit from aberration correction.

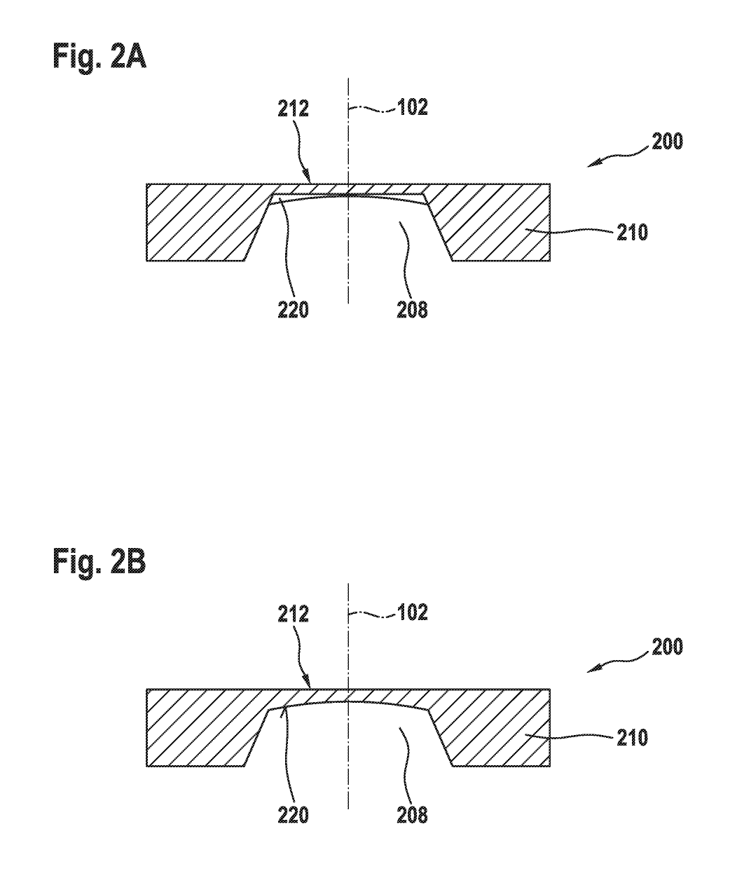

According to some embodiments, which can be combined with other embodiments described herein, a membrane of solid material, such as a thin membrane of solid material, is provided in the aberration correction aperture 200. The aberration correction aperture 200 includes an aperture body 210 having a transparent aperture portion. The transparent aperture portion is configured for having the primary charged particle beam passing through the transparent aperture portion. For example the transparent aperture portion can be an aperture opening or a thin membrane. A membrane portion 220 including a solid material is provided in the aberration correction aperture. The charged particle beam passes through the solid material, wherein a phase shift is provided to the charged particle beam. A varying thickness of the membrane portion introduces a phase shift e.g. for reducing aberrations, particularly spherical aberrations. Further details regarding the aberration correction aperture 200 are described with respect to FIGS. 2A to 5C.

FIG. 1 shows the scanning charged particle beam apparatus 100. The charged particle beam source 110 includes an emitter 116 having a tip, such as a sharp tip. Further, a suppressor 114 and an extractor 112 can be provided. According to some embodiments, which can be combined with other embodiments described herein, a high brightness, low energy width source can be provided. For example, a field emitter can be provided as the charged particle beam source. The field emitter can be a thermal field emitter (TFE) or a cold field emitter (CFE). Also other charged particle beam sources having a reduced brightness of 5·10⁷ A/m²·sr·V or above and an energy width of 1 eV or below can be provided.

The extractor 112 accelerates the primary charged particle beam to a high column energy, for example 10 keV or above, 12 keV or above, such as for example 30 keV. Also column energies above 30 eV can be provided according to embodiments described herein. The primary charged particle beam can be guided at the high column energy in tube 113. According to embodiments described herein, an electrode arrangement for accelerating the primary charged particle beam can be provided. For example, the electrode arrangement for acceleration can include one or more of the extractor 112, the tube 113, and a further electrode having a high potential as compared to the emitter tip. According to some embodiments, which can be combined with other embodiments described herein, a scanning charged particle beam apparatus as described herein kay have a charged particle beam source having an energy width of 0.8 eV or below, e.g. wherein the charged particle beam source is a field emitter; and wherein the scanning charged particle beam apparatus further comprises an electrode arrangement for accelerating the primary charged particle beam to a column energy of 10 keV or above, e.g. 30 keV or above.

A deceleration electrode 138 decelerates the charged particles to low landing energy for impingement on the specimen 140. For example, the specimen 140 can be provided on the specimen support 142. The specimen support 142 can be a movable stage for positioning the specimen 140. For example, the movable stage can be configured for moving the specimen 140 in one direction (e.g. X direction) or in two directions (e.g. X-Y-directions).

In the example shown in FIG. 1, the objective lens 130 is provided by a magnetic lens portion and an electrostatic lens portion. The magnetic lens portion can be provided by pole pieces 132 in which coils 134 are provided. The electrostatic lens portion is provided by guiding the charged particles at a high potential in tube 113, or another similar electrode and the deceleration electrode 138, such that a decelerating electrostatic lens component is provided. According to some embodiments, which can be combined with other embodiments described herein, the deceleration of the primary charged particle beam can be provided in the vicinity of the specimen, for example in or behind the objective lens, or a combination thereof. For example, a retarding bias voltage can be applied to the specimen and/or the substrate support in order to provide a decelerating electrostatic lens component according to embodiments described herein. The objective lens can be an electrostatic-magnetic compound lens having e.g. an axial gap or a radial gap, or the objective lens can be an electrostatic retarding field lens. According to some embodiments, which can be combined with other embodiments described herein, a scanning charged particle beam apparatus as described herein may include a deceleration electrode configured for decelerating the primary charged particle beam before impingement on the specimen. Yet further, embodiments describe herein can provide a high energy of the charged particle beam within the column, e.g. in tube 113, and a low landing energy. For example, the high energy can be 10 keV or above, e.g. 30 keV or above and the low landing energy can be 2 keV or below, e.g. 1 keV or below. Accordingly, the decelerating electrostatic lens component can be configured for a deceleration of a factor of 5 or more, e.g. a factor of 10 or more.

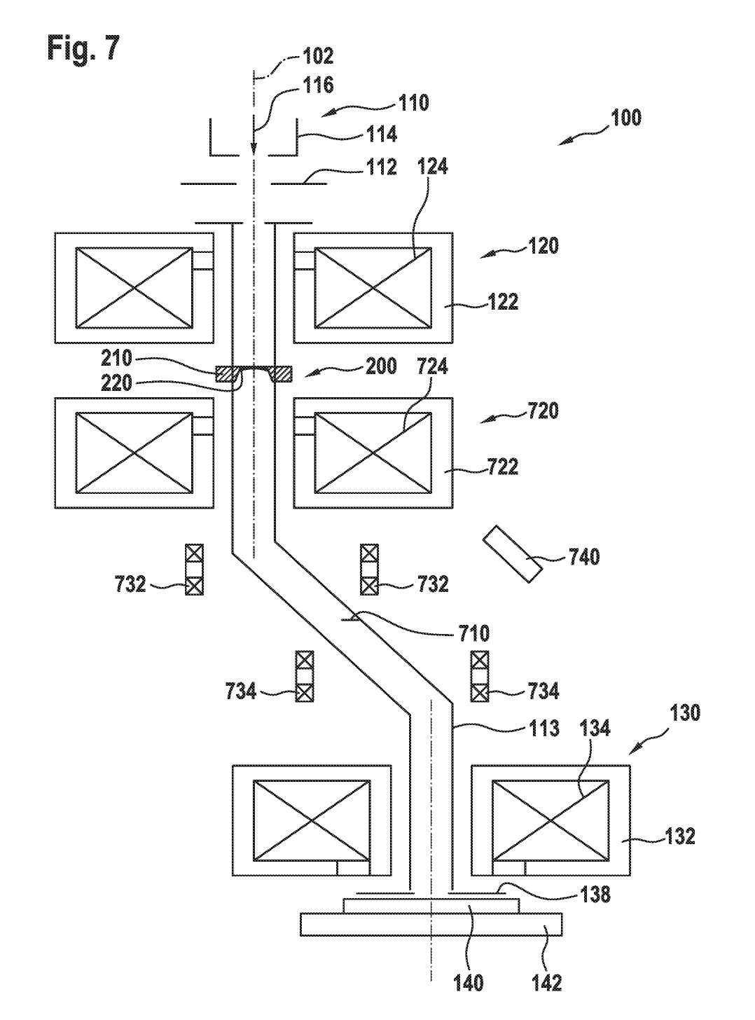

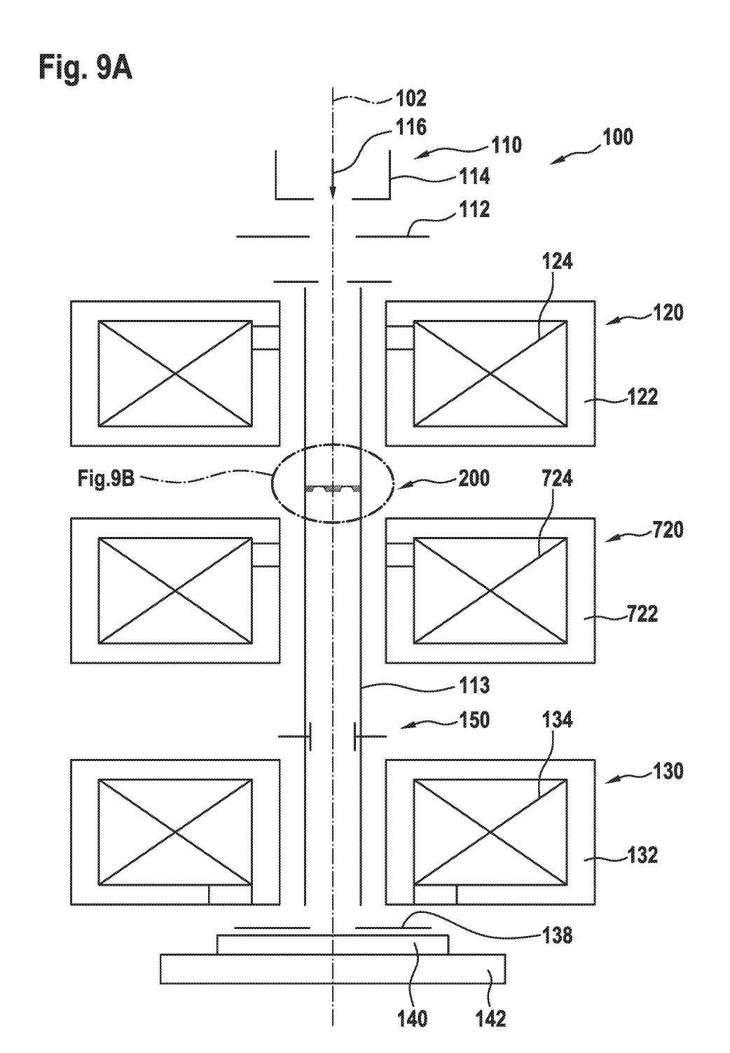

As shown in FIG. 1, a condenser lens 120 can be provided. The condenser lens can be magnetic as shown in FIG. 1 and have pole pieces 122 and coil 124. Alternatively, the condenser lens can be electrostatic or combined magnetic-electrostatic. According to embodiments described herein, the condenser lens can be for probe size and/or current control. According to yet further embodiments, a second condenser lens can be provided as shown in FIGS. 7 and 9.

According to some embodiments, which can be combined with other embodiments described herein, the aberration correction aperture can be the beam limiting aperture of the scanning charged particle beam apparatus. Charged particle beam apparatuses normally have one or more apertures, which determine the system aperture angle of the scanning charged particle beam apparatus. To reduce the spot size on the specimen, i.e. the size of the probe formed by the primary charged particle beam on the specimen, lens aberrations are corrected. According to embodiments described herein, the lens aberrations are corrected for the portion of the primary charged particle beam, which is within the system aperture angle of the scanning charged particle beam apparatus. Accordingly, large correction elements with wide correction areas, which cover also portions of the primary charged particle beam, which are not used for forming of the probe on the specimen, can be avoided. For example multipole correctors may act on all charged particles in the primary charged particle beam in a wide area. Thus, according to some embodiments, correction of the primary charged particle beam can be limited to those portions of the primary charged particle beam which ultimately impinge on the specimen.

FIG. 2A shows an example of an aberration correction aperture 200. The aberration correction aperture 200 includes an aperture body 210 having a transparent aperture portion 212. The transparent aperture portion 212 is the portion of the aperture, which allows for passing of the beam of charged particles through the aperture. A membrane portion 220 is provided at or in the transparent aperture portion, wherein the membrane portion includes a solid material through which the charged particle beam passes on the way from the charged particle source to the specimen. The membrane portion 220 has a varying thickness, such that a phase shift is introduced in different portions of the charged particle beam.

The transparent aperture portion 212 and the membrane portion 220 is provided with a thickness of e.g. 1 nm to 100 nm. For example the transparent aperture portion can have a thickness of 25 nm, and the membrane portion can have a thickness of maximum 75 nm. Accordingly, according to some embodiments, which can be combined with other embodiments described herein, the total maximum thickness of the transfer and aperture portion together with the membrane portion can be 100 nm or below, for example 80 nm or below, such as 10 nm to 75 nm.

Particularly the membrane portion can be made of light material to minimize electron scattering. For example materials like silicon, carbon, silicon oxide, silicon nitride can be used. Optionally, also the transparent aperture portion can be provided from a similar material or the same material.

According to yet further embodiments, which can be combined with other embodiments described herein, the transparent aperture portion 212 can also be an opening in the aperture body 210. Having an opening in the aperture body 210 might increase the complexity to manufacture, attach or provide the membrane portion at or within the transparent aperture portion. Accordingly, embodiments having a transparent aperture portion 212 with a thickness larger than zero, for example a thin carrier for a membrane portion, allow for easier manufacturing of the aberration correction aperture.

As shown for example in FIG. 2A, that transparent aperture portion 212 can be provided in the aperture body 210 by providing a recess 208 in the aperture body 210. For example the recess 208 can be manufactured by a mechanical process such as milling, by an etching process, or by a combination thereof. The example shown in FIG. 2A includes a recess 208 and one side of the aberration correction aperture 200. Other embodiments, which can be combined with yet further embodiments described herein, may also have a first recess 208 at one side of the aperture body 210 and a further recess 209 at an opposing side of the aperture body 210 (see e.g. FIG. 2C).

According to embodiments described herein, the membrane portion 220 and the transparent aperture portion 212 have a rotational symmetry, particularly around the center of the aperture opening, which may for example coincide with optical axis 102 of the penetrating charged particle beam. Yet further, the aberration correction aperture and/or the aperture body may optionally also share the same rotational symmetry. Accordingly, in light of the rotational symmetry, the varying thickness is provided in a radial direction from the center of symmetry, e.g. the optical axis 102.

The charged particle beam experiences in its radial direction different phase shifts according to the different number of membrane atoms involved when the charged particle beam passes through the solid material. The radial thickness distribution of the membrane portion is configured such that the phase shift inside the membrane compensates spherical aberrations, for example spherical aberrations of the objective lens, spherical aberrations of the condenser lens, or spherical aberrations of the objective lens and the condenser lens. Accordingly, a spherical aberration correction or a reduction of spherical aberrations can be achieved.

As for example shown in FIG. 2A and similarly in other embodiments showing an aberration correction aperture 200, the aperture body 210 has a radially outer portion with an increased thickness, wherein charged particles of the charged particle beam are blocked outside of the transparent aperture portion 212. A beam blocking portion is formed around the transparent aperture portion 212, wherein the beam blocking portion is configured to block charged particles. A correction within the membrane portion can be provided such that the membrane portion is placed in the beam limiting aperture, i.e. the transparent aperture portion 212.

FIG. 2B shows a further example of an aberration correction aperture 200. The aperture body 210 has a recess 208. As compared to FIG. 2A, the transparent aperture portion 212 and the membrane portion 220 are integrally formed. This can for example be provided by an etching process. For such embodiments, the combination of the transparent aperture portion 212 and the membrane portion has a varying thickness. The membrane portion 220 and the transparent aperture portion 212 have a rotational symmetry, particularly around the center of the aperture opening, which may for example coincides with optical axis 102 of the penetrating charged particle beam.

FIG. 2C shows another embodiment, wherein the aperture body 210 has the first recess 208 and a second recess 209 at an opposing side. The membrane thickness variation can be provided either from the front side or back side of the aberration correction aperture. For example, FIGS. 2A and 2B show a membrane thickness variation at the backside. For example FIGS. 2C and 2D show a membrane thickness variation at the front side.

A membrane or an area through which the charged particle beam passes can include a transparent aperture portion, i.e. a bulk area, for example in which the beam aperture diameter is defined, and a thin membrane, e.g. a membrane portion 220, whose thickness increases radially for phase shift generation which is used for aberration correction. According to some embodiments, in order to keep electron scattering small the membrane portion can be thinner at its center. The radial thickness increase, which generates the intended phase shift, is determined by the aberration coefficient of the lenses used.

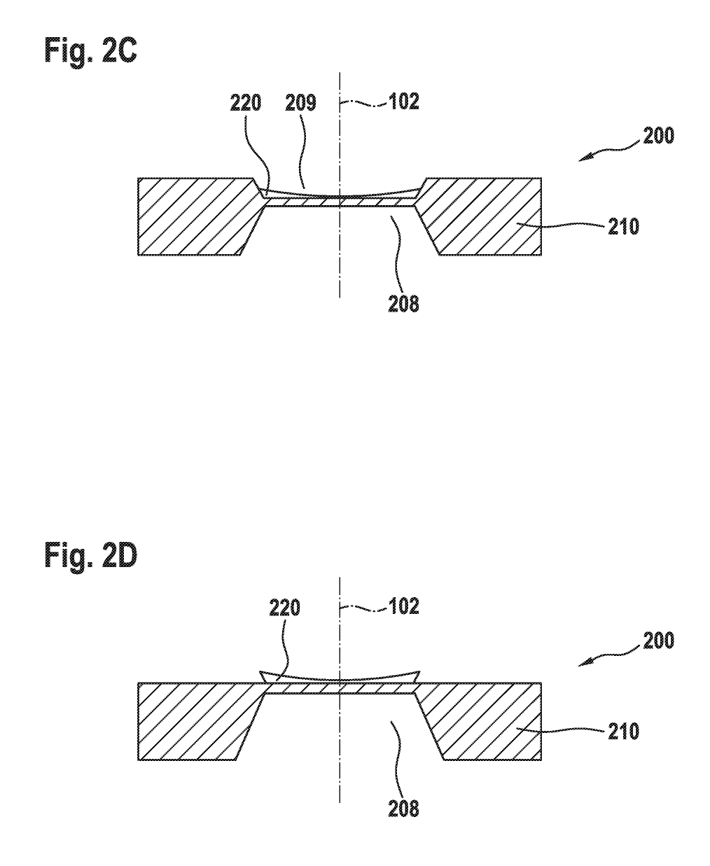

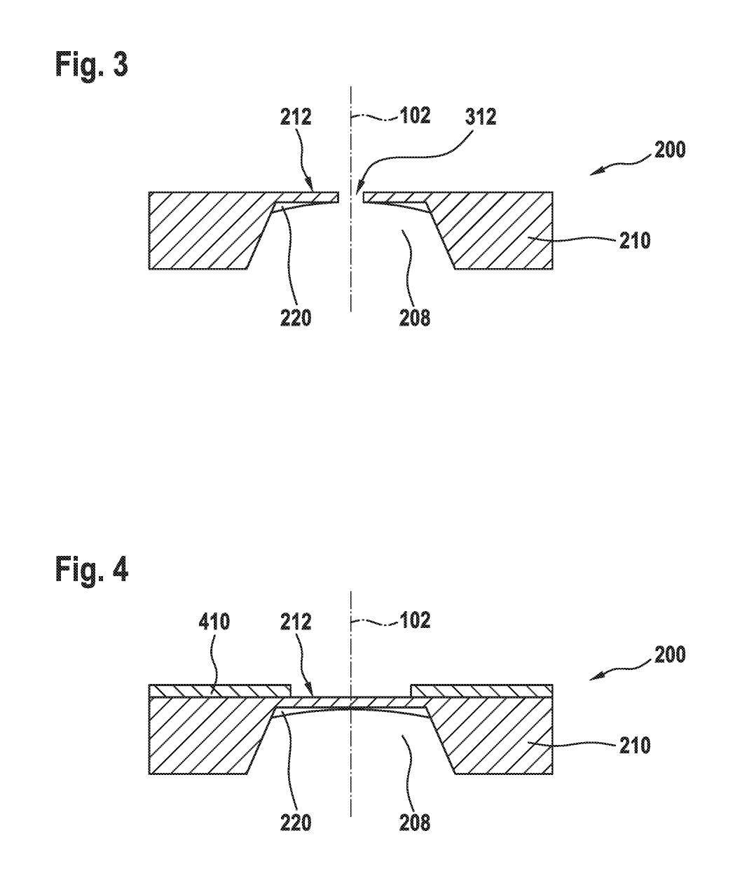

In the further example of an aberration correction aperture 200, the membrane portion 220 is provided on top of the transparent portion within the aperture body 210. In light of the above, according to different examples, manufacturing of a membrane, through which the charged particle beam passes for aberration correction, can be provided by different techniques. The shaped membrane can be manufactured as one piece. For example, according to some embodiments, the membrane can be as thin as possible in the center thereof, wherein the thickness increases towards the rim, i.e. with increasing radius. This is for example shown in FIG. 2B. Alternatively, a thin carrier, i.e. a transparent aperture portion 212, for example a foil or a thin carrier foil, can be provided. A membrane portion, for example a shaped membrane can be provided on top of the transparent aperture portion, i.e. the foil, or below the transparent aperture portion. Corresponding examples are shown in FIGS. 2A, 2C and 2D, as well as FIGS. 3 and 4.

According to yet further embodiments, which can be combined with other embodiments described herein, a beneficial aberration correction aperture 200 can be provided as shown in FIG. 3. A central hole 312 is provided in the transparent aperture portion 212 and the membrane portion 220. The central hole 312 can have a hole diameter, which creates an electron beam bundle without any significant axial aberrations. Having a central hole 312, the percentage of scattered electrons can be reduced, which may contribute to a background signal.

According to other implementations (see for example FIG. 4), which can additionally or alternatively be provided, the transparent aperture portion 212 together with the membrane portion 220 can be provided to be transparent. The beam limiting area of the aperture body 210 can be provided with a metal coating 410. Accordingly, electrons which are blocked by the beam limiting area or the beam blocking portion do not charge the aberration correction aperture 200 but can be guided with a connection to a predetermined potential, for example the column potential.

According to embodiments described herein, the membrane portion can be a part of the beam limiting aperture, i.e. the final beam aperture or the system aperture. Accordingly, the membrane portion is provided in the system aperture defining the overall system aperture. This can result in a self-centering effect of the aberration correction aperture.

According to yet further embodiments, which can be combined with other embodiments described herein, also the membrane portion and the transparent aperture portion can be made of the conductive material. Portions of the aberration correction aperture 200 being made of a conducting material enables to bias the aberration correction aperture, e.g. the portion being in direct contact with the charged particle beam, to the respective potential of the column, at which the aberration correction aperture is positioned. Accordingly, an electrostatic influence of the aberration correction aperture on the charged particle beam can beneficially be reduced or avoided. If the aperture and/or the membrane is not electrically conductive, the aperture and/or the membrane can be coated by an additional thin electrically conductive coating, e.g. by sputtering a few nanometer of carbon. According to yet further additional or alternative embodiments, one or more layers can be provided on the membrane for reduction or prevention of contamination and/or for reduction or prevention of charging on the membrane. Particularly layers or membrane materials for preventing or reduction of charging of the membrane can be beneficial for maintaining the membrane at the same potential as compared to the column of the scanning charged particle beam apparatus.

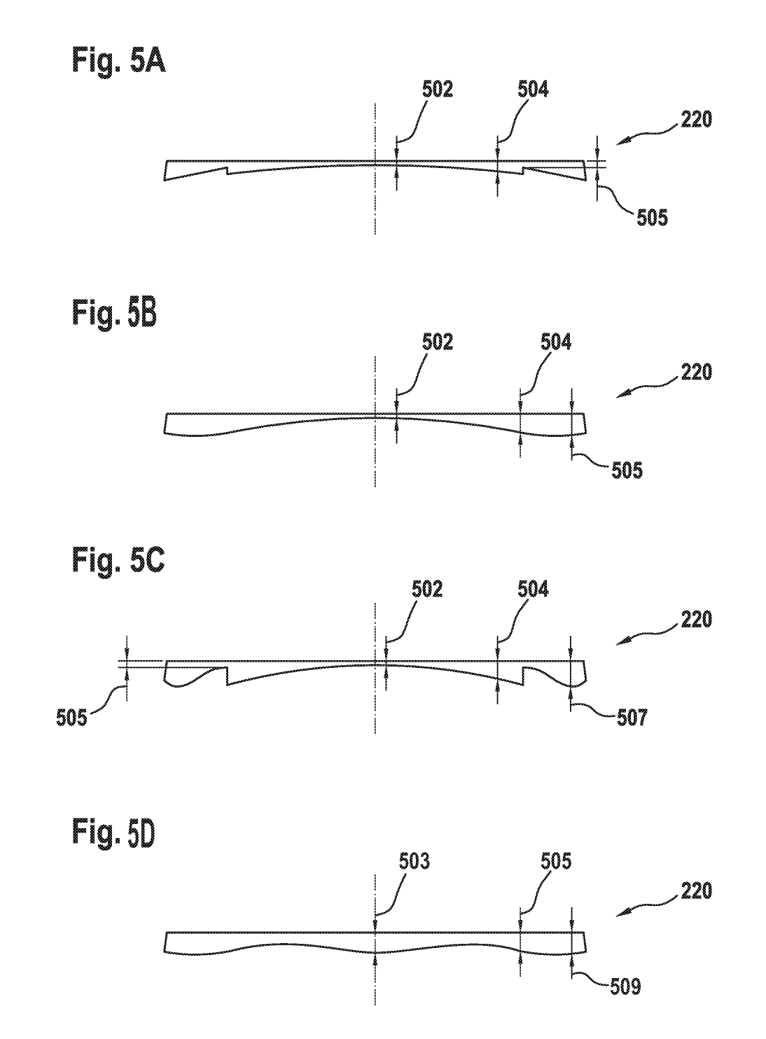

Different aspects of the thickness distribution, which can be utilized according to embodiments described herein, are described with respect to FIGS. 5A, 5B, and 5C. Embodiments described herein, may have thickness distributions, with a rotational symmetry, particularly a rotational symmetry around the center of the system aperture, for example around the optical axis 102. According to some embodiments described herein, the thickness in the center of rotation might have a minimum or a local minimum. For example, this thickness may radially increase from the center outwardly with an increasing distance from the center.

The thickness distribution can be determined by using one or more of the aberration coefficients, wherein for example values for a spherical aberration coefficient C_{S} and/or the chromatic aberration coefficient C_{C} related to the sample side can be in the range of 0.2 mm to 10 mm. Further, additionally or alternatively, phase shift calculations using the material properties of the membrane portion 220 and/or the transparent aperture portion 212 can be utilized for determining the thickness distribution.

According to some embodiments, a thickness increase from the center can follow a polynomial as function of radius. FIG. 5A shows a comparably small thickness 502 at or adjacent to the center of the membrane portion 220. A larger thickness 504 is provided at a position, which is radially outward as compared to the thickness 502. The membrane portion introduces a radially dependent phase shift for the charged particles in the charged particle beam. A phase shift of 2π equals a zero phase shift. Accordingly, a reduced thickness 505 can be provided at a position, which is radially outward as compared to the thickness 504. The radial position of reduced thickness can be provided for the case that a phase shift equals 2π and the membrane portion thickness distribution is provided with a step function in dependence of the radius. Introducing the step function in the thickness distribution as soon as a thickness corresponding to a phase shift of 2π is achieved results in the benefit, that the material thickness of the membrane portion can be reduced. Accordingly, scattering of charged particles in the solid material can be reduced. FIG. 5B shows a further example of a membrane portion 220 having a small thickness 502 at or adjacent to the center of the membrane portion. A larger thickness 504 is provided at a position, which is radially outward as compared to the thickness 502. For even further larger radiuses, the thickness 507 is smaller as compared to the thickness 504. Accordingly, in a concentrically outer portion of the membrane a further defocusing effect can be provided for the axially outer portion of the charged particle beam passing through the membrane portion. FIG. 5C shows an example of the membrane portion 220 having a thickness 505 at a radial position of a step function and an outer reduced thickness 507 for defocusing, which is explained with respect to FIGS. 5A and 5B.

According to yet further embodiments, which can be combined with other embodiments described herein, the thickness 503 of the membrane at the center can also have a local maximum, in order to provide a defocusing of the charged particle beam. This is shown exemplarily in FIG. 5D. For example, the center can have a thickness variation in the vicinity of the center, which is a function of r², wherein r is the radius. The thickness can decrease to a thickness 505 with increasing radius and thereafter can increase again to a thickness 509 for further increasing radiuses. The subsequent thickness increase may have a thickness variation, which is a function of r⁴, wherein r is the radius. Utilizing embodiments, with a local maximum thickness at the center, the overall thickness might be reduced, particularly in combination with an additional lens defocusing, e.g. of an objective lens. The defocusing of the membrane portion, i.e. the defocus by the phase shift, can be compensated by defocusing the objective lens in the opposite direction.

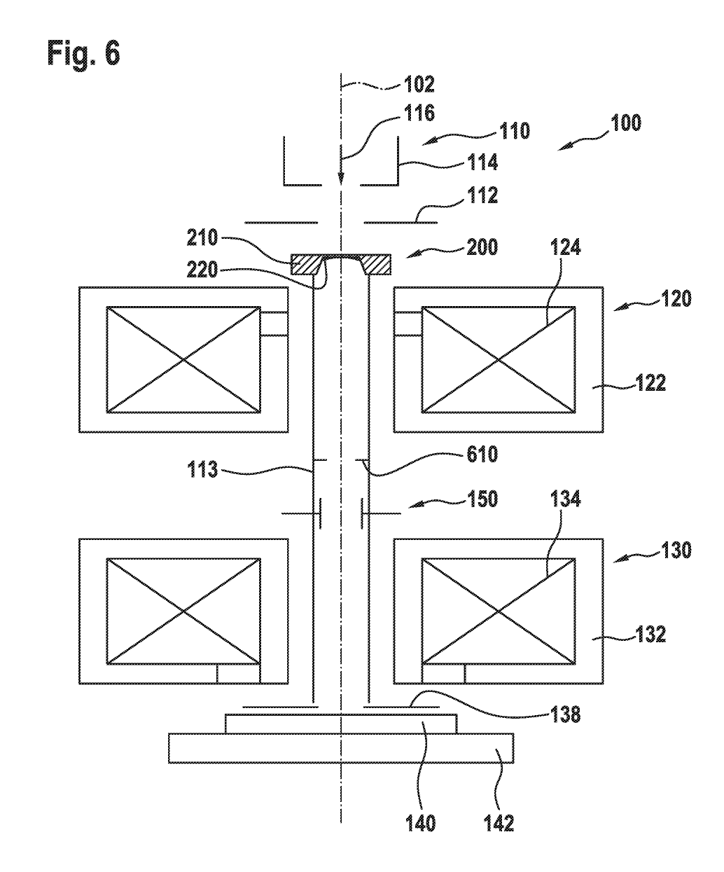

FIG. 6 shows a further scanning charged particle beam apparatus 100, which is comparable to the scanning charged particle beam apparatus shown in FIG. 1, and for which features described with respect to FIG. 1 may similarly be included. A charged particle beam source 110 generates a primary charged particle beam. The primary charged particle beam is guided in the scanning charged particle beam apparatus 100 and is focused on a specimen 140 by objective lens 130. A scanning deflection assembly 150 scans the probe over the surface or surface area of the specimen 140. By scanning the probe over the surface of the specimen, an image can be generated. The scanning deflection assembly 150 shown in FIG. 6 is an electrostatic deflection assembly as compared to the magnetic deflection assembly shown in FIG. 1. The deflection assembly may also include more than 1 stage. According to yet further embodiments, at combined electrostatic-magnetic deflection assembly can also be used for scanning the charged particle beam over a specimen.

An aberration correction aperture 200 is provided in the scanning charged particle beam apparatus 100. Particularly, the aberration correction aperture can be provided as a beam limiting aperture, i.e. the aperture defining the system aperture of the scanning charged particle beam apparatus. The aberration correction aperture 200 includes a membrane of solid material, such as a thin membrane of solid material. The charged particle beam passes through the solid material, wherein a phase shift is provided to the charged particle beam. A varying thickness of the membrane portion introduces a phase shift for reducing aberrations, particularly spherical aberrations. Further details regarding the aberration correction aperture 200 are described with respect to FIGS. 2A to 5C.

To eliminate scattered electrons which are generated within the membrane and which may increase spot size or reduce contrast, a spray aperture 610 may be introduced according to some embodiments, which can be combined with other embodiments described herein. Since scattered electrons will have experienced energy losses, beneficial positions of the spray aperture are e.g. behind the condenser lens 120 or behind deflection systems (see e.g. deflection stages 732-734 in FIG. 7). Elements like the condenser lens or deflection system can deflect scattered electrons, which have a reduced energy, away from or out of the primary beam path. Accordingly, some embodiments may include a spray aperture, which is positioned downstream along the primary charged particle beam of the aberration correction aperture, wherein the spray aperture is configured for blocking charged particles scattered from the aberration correction aperture, particularly wherein the scattered charged particles are deflected out of a primary beam path.

FIG. 7 shows a yet further embodiment of a scanning charged particle beam apparatus. The charged particle beam apparatus 100 shown in FIG. 7 includes a first deflection stage 732 and a second deflection stage 734, for displacing the optical axis. In FIG. 7, a spray aperture may also be provided as a knife edge 710. The scattered electrons with the reduced energy are deflected out of the primary charged particle beam path in one direction. Accordingly, a spray aperture can be provided as a knife edge, which delimits the beam path at one side as compared to the concentric aperture. According to different implementations, a spray aperture can be provided downstream of an element, e.g. a dispersion element, selected from the group consisting of: a monochromator, an electrostatic deflector, a magnetic deflector, a combined magnet electrostatic deflector, e.g. a Wien filter, and combinations thereof. For example, the dispersion element can be a magnetic deflector or a 2-stage or 4-stage magnetic deflection assembly or a monochromator. The dispersion element in combination with a stray aperture can remove electrons scattered in the membrane portion and which experienced energy losses by the scattering. That is, a spray aperture can be provided downstream of an element deflecting charged particles, which have been scattered in the membrane portion, out of the primary beam path. The scattered charged particles, which have been scattered in the membrane portion have a reduced energy as compared to the primary charged particle beam and are beneficially not utilized for forming of the probe, which is scanned over the specimen. In light of the above, according to some embodiments, a scanning charged particle beam apparatus according as described herein, may include a spray aperture, which is positioned downstream along the primary charged particle beam of the aberration correction aperture, wherein the spray aperture is configured for blocking charged particles scattered from the aberration correction aperture, wherein the charged particles scattered from the aberration correction aperture are deflected out of a primary beam path.

FIG. 7 shows a further scanning charged particle beam apparatus 100, which is comparable to the scanning charged particle beam apparatus shown in FIGS. 1 and 6, and for which features described with respect to FIGS. 1 and 6 may similarly be included, i.e. mainly the differences with respect to embodiments described with respect to FIGS. 1 and 6 are described. The scanning charged particle beam apparatus 100 shown in FIG. 7 includes a second condenser lens 720, for example the second condenser lens can be a magnetic condenser lens having pole pieces 722 and coils 724. Alternatively, the second condenser lens may be an electrostatic condenser lens or a combined magnetic-electrostatic condenser lens. The second condenser lens can provide an element for aperture control, i.e. controlling the system aperture of the scanning charged particle beam apparatus. Accordingly, in addition to control of probe size and/or probe current provided by a first condenser lens, the second condenser lens can be utilized for controlling a further parameter.

As shown in FIG. 7, the aberration correction aperture 200 can be provided between the first condenser lens 120 and the second condenser lens 720. According to yet further embodiments, which can be combined with other embodiments described herein, other positions can be used for any of the scanning charged particle beam apparatus 100 described within the present disclosure. The position of the aberration correction aperture along the optical axis may depend upon the electron optical setup and/or membrane manufacturing limitations. For example, an electron optical setup can be provided, wherein the aberration correction aperture is in the vicinity of the lens, which aberrations are to be corrected or reduced. For example membrane manufacturing limitations may be the ability to manufacture a membrane portion of a certain diameter. Accordingly, the aberration correction aperture may be positioned at a position along the optical axis for which the membrane portion can be manufactured to have a varying thickness according to embodiments described herein. According to some embodiments, the aberration correction aperture 200 can be provided between the charged particle beam source and the specimen.

The deflection system provided by the first deflection stage 732 and the second deflection stage 734 is further configured to separate a primary charged particle beam from a signal charged particle beam. Signal charged particles, which are generated on impingement of the primary charged particle beam, i.e. the probe, on the specimen 140, are accelerated towards the objective lens 130 and through the objective lens. In light of the velocity of the signal charged particles as compared to the primary charged particles, the signal charged particles are deflected by the second deflection stage 734 towards the detector 740. According to other embodiments, additionally or alternatively, on-axis detectors may be used for detecting the signal charged particles generated on impingement of the probe on the specimen.

The scanning charged particle beam apparatus as exemplarily shown with respect to FIG. 7 may be utilized for example for electron beam inspection (EBI). Particularly for electron beam inspection tools, a high probe current inside the electron probe is a boundary condition for getting a small probe with high current density at the specimen, which enables high throughput. At high currents, also electron-electron interaction has an influence large enough to be another limiting factor for higher current density in the probe. Consequently for the performance improvement of such high current density optics spherical aberration correction/reduction is of interest. Accordingly, aberration correction apertures as described herein, which may particularly allow for improved spherical aberration correction, can be beneficially utilized for EBI tools. The improved spherical aberration correction allows for larger system apertures, which can reduce the current density along the beam path for a given probe current.

According to some embodiments described herein, the aberration correction aperture 200 is beneficially provided as a beam limiting aperture, wherein only charged particles participating in forming the probe on the specimen pass through the correction aberration aperture and are provided with a phase shift therein. The phase shift depends on the radial position on the membrane portion, which is the distance from the optical axis.

According to other embodiments, which can be combined with the embodiments, the aberration correction aperture and the beam limiting aperture can be provided as two different components along the optical axis. This can be realized close to each other in z-direction (along the optical axis), for example at the distance of 20 mm or below, wherein a separation between the beam limiting aperture and the aberration correction aperture has less influence on the optical properties but may be rather motivated by manufacturing capabilities. Alternatively, the aberration correction aperture and the beam limiting aperture can be separated along the path of the charged particle beam, wherein for example an optimization for another function in the beam pass is provided. For example, the beam limiting aperture can be provided in correlation with a beam blanking aperture. According to yet further embodiments, which can be combined with other embodiments described herein, a spray aperture 610 as shown in FIG. 6, may also provide a beam limiting aperture, i.e. a system aperture defining element.

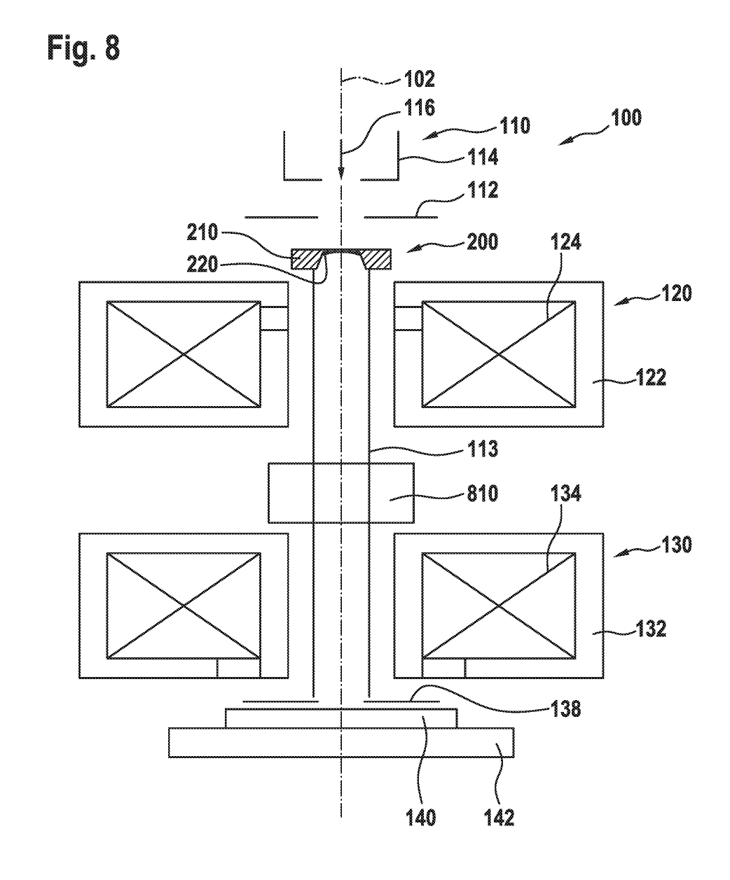

FIG. 8 shows a further scanning charged particle beam apparatus 100, which is comparable to the scanning charged particle beam apparatus shown in FIGS. 1, 6, and 7, and for which features described with respect to FIGS. 1, 6 and 7 may similarly be included, i.e. mainly the differences with respect to embodiments described with respect to FIGS. 1, 6, and 7 are described.

According to embodiments described herein, the charged particle beam source 110 can be provided as a field emitter, for example TFE or CFE cathodes, having a low energy width. For example, the energy width can be 0.8 eV or below. The small energy width can shift the optimum system aperture of the scanning charged particle beam apparatus to larger aperture angles due to a reduced chromatic aberration. Accordingly, spherical aberration correction, particularly with an improved aberration correction aperture as described herein, is beneficial for systems having a low energy width in the primary charged particle beam.

In light thereof, according to some embodiments, which can be combined with other embodiments described herein, the scanning charged particle beam apparatus 100 shown in FIG. 8 includes a monochromator 810. The monochromator 810 can be utilized to further reduce the energy width. The monochromator selects a reduced energy band from the emission spectrum of the charged particle beam source. As a further alternative or additional implementation, a combined chromatic and spherical aberration corrector may be utilized. For example, the spherical aberrations can be corrected by an aberration correction aperture according to embodiments described herein. Chromatic aberrations may be corrected by a mirror corrector or a multipole corrector, wherein for example one or more quadrupole and octopole correctors are combined for correction of chromatic aberrations.

According to yet further embodiments, which can be combined with other embodiments described herein, the beam energy of the charged particle beam within the column, for example within tube 113 and/or between an extractor 112 and a deceleration electrode 138 can be 10 keV or above, e.g. 30 keV or above. The high beam energy within the column of the scanning charged particle beam apparatus reduces chromatic aberrations and further allows charged particles of the charged particle beam to more easily pass through the solid material of the membrane portion and, if existent, a solid material of the transparent aperture portion of aberration correction apertures described herein.

As shown in FIG. 8, a monochromator 810, which is provided in the direction of the primary charged particle beam behind the aberration correcting aperture 200, can be provided. For example, if the correcting aperture is designed for spherical aberration correction, the monochromator improves resolution not only by reducing the energy width of the charged particle beam and energy broadening of the charged particle beam by electron-electron interaction, but also sorts out charged particles, which suffer from energy losses in the membrane portion of the scanning charged particle beam apparatus.

According to various implementations, a monochromator can for example be provided as a filter lens, an Ω-filter, a Wien filter, or a mirror filter. According to some embodiments, for scanning charged particle beam apparatuses utilizing a CFE source, a filter lens type monochromators might be a beneficial solution in light of its simplicity. According to embodiments, which can be combined with other embodiments described herein, a filter lens-type monochromator may include a retarding lens adapted to be a high-pass energy filter for the primary charged particle beam.

FIGS. 9A and 9B illustrates a yet further embodiment of scanning charged particle beam apparatus 100. An aberration correction aperture 200 is provided between a first condenser lens 120 and a second condenser lens 720. The aberration correction aperture 200 has an aperture body 210 including two transparent aperture portions 212 and 212-2, respectively, wherein a first membrane portion 220 and a second membrane portion 220-2 are provided in a respective area of one of the two transparent aperture portions. For example, two recesses are formed in the aperture body 210. The first membrane portion 220 has a rotational symmetry with respect to the first optical axis 102 and the second membrane portion 220-2 has a rotational symmetry with respect to a second optical axis 102-2. According to some embodiments, which can be combined with other embodiments described herein, one membrane portion can be provided in a scanning charged particle beam apparatus as described with respect to FIGS. 1 to 8, or two or more membrane portions can be provided in a scanning charged particle beam apparatus. FIGS. 9A and 9B exemplarily show two membrane portions.

For generation of different spot sizes in the scanning charged particle beam apparatus, different demagnifications can be provided in the optical system. Accordingly, different focal lengths of the lenses, for example the condenser lens and the objective lens, are provided. As a result different aperture opening sizes may be utilized, which can further result in a variation of the aberration coefficients of the one or more lenses, which are to be corrected. In light thereof, according to some embodiments, the aperture membrane, i.e. membrane portion, can be designed for two or more spot sizes. A membrane area and/or thickness distribution can be provided for two or more spot sizes in the scanning charged particle beam apparatus. Accordingly one or more, for example two, three, four, five, or six membrane portions can be provided.

In the example shown in FIGS. 9A and 9B having two membrane portions, the deflection system can be provided in the scanning charged particle beam apparatus, which is configured for guiding the charged particle beam along the first optical axis 102 or the second optical axis 102-2, particularly for trespassing through the aberration correction aperture 200. Yet further, additionally or alternatively, one or more of the membrane portions according to embodiments described herein, can have a thickness distribution, which reduces or compensates the objective lens aberrations and aberrations of the one or more condenser lenses, particularly in cases where the condenser lens contributes significantly to the overall system aberrations.

According to yet further embodiments, which can be combined with other embodiments described herein, the aberration correction aperture can be provided either as a single aperture having one membrane portion or as a multi-aperture having two or more membrane portions. For example, the aberration correction aperture can be fixed in location relative to the charged particle beam column or can be movable to be mechanically aligned within the column. Multi-aperture aberration correction apertures allow for a fast selection of individual charged particle beam paths, for example for different system demagnifications, which may be introduced by specific condenser lens and objective lens settings. Accordingly, different modes of operation can be addressed, wherein between two or more membrane portions can be switched for the modes of operation.

FIGS. 9A and 9B show embodiments for which a primary charged particle beam is deflected to travel along a first optical axis 102 or a second optical axis 102-2. Accordingly, the first membrane portion 220 and a second membrane portion 220-2 can be provided to be each rotational symmetric for correction of spherical and/or chromatic aberrations. Afterwards, the charged particle beam can be deflected back onto the optical axis of the objective lens.

According to yet further embodiments, a multi-aperture may also be provided to generate two or more beamlets from one primary charged particle beam. That is, two or more beamlets are generated simultaneously and the plurality of beamlets has a center rotational axis or optical axis. In other words, the optical axis of the scanning charged particle beam device is not deflected in this area of the aberration correction aperture. In such a case, a rotational symmetry can be provided for the assembly of membrane portions. For example, the assembly of two or more membrane portions can have a similar thickness distribution in the regions of the individual membrane as compared to one large membrane for all beamlets, which would rotation symmetric. Each individual membrane portion which is provided off-axis from the optical axis along which the primary charged particle beam, i.e. the primary charged particle beam being divided into beamlets, travels, might in such a case not include a rotational symmetry. According to embodiments described herein, a rotational symmetry of one membrane portion or a rotational symmetry of two or more membrane portions (n-fold symmetry for an assembly of n membranes) can be provided with respect to the optical axis of the primary charged particle beam. The primary charged particle beam may be provided by one charged particle beam traveling along the optical axis or by two or more beamlets of the primary charged particle beam, wherein each beamlet may travel off-axis.

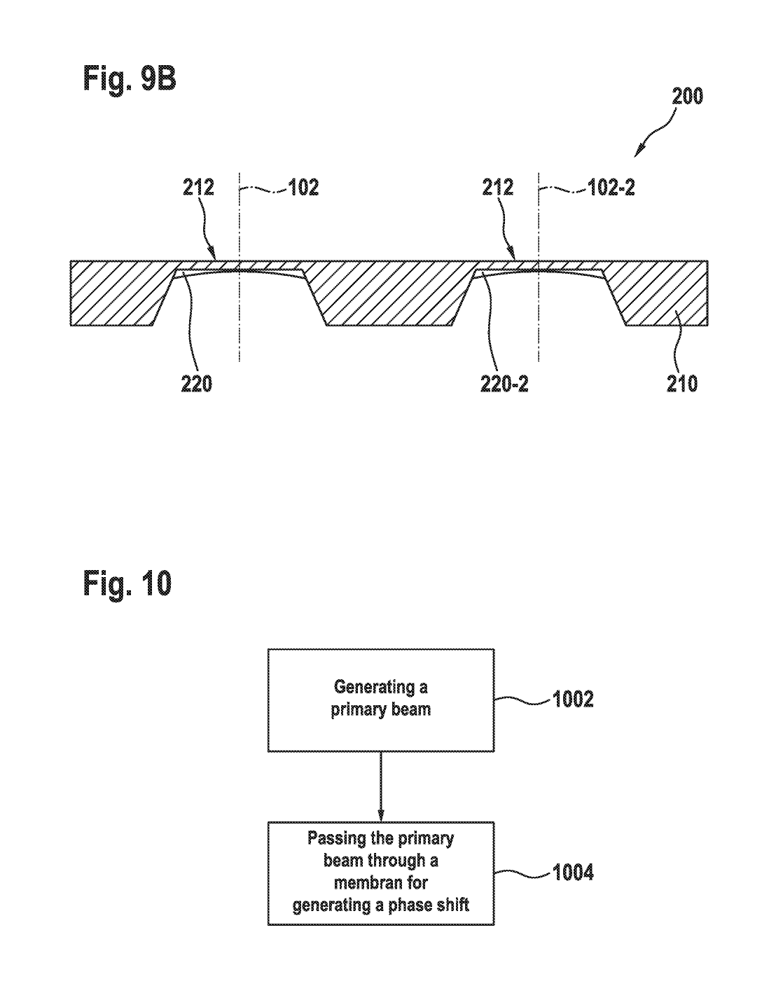

FIG. 10 shows a flow chart for illustrating a method of operating a scanning charged particle beam apparatus according to embodiments described herein. In block 1002 a primary charged particle beam is generated. In block 1004, aberrations of the primary charged particle beam are corrected with an aberration correction aperture, wherein at least a portion of the primary charged particle beam passes through a membrane portion of the aberration correction aperture for introducing a phase shift within the primary charged particle beam. According to yet further optional modifications, the aberration correction aperture may also delimit the system aperture of the scanning charged particle beam apparatus.

The present disclosure provides a simple solution, e.g. for spherical aberration correction. Due to the high robustness of the aberration correction apertures described herein, the lack of spherical aberration correction in SEMs, which are used in a production environment, can be overcome. According to some embodiments, which can be combined with other embodiments described herein, the scanning charged particle beam devices can particularly be SEMs for CD (critical dimensioning), DR (defect review), or EBI (electron beam inspection), and beneficially have a high robustness. In particular for EBI, spherical aberration correction not only reduces the spherical aberration itself but also reduces the influence of electron-electron interaction based upon the following effect. By enabling larger aperture angles the current inside the optical system can be spread over a wider aperture angle area which reduces electron-electron interaction. According to yet further embodiments, which can be combined with other embodiments described herein, the membrane portions and particularly the varying thickness thereof can be configured for additionally providing correction of chromatic aberrations. The thickness distribution of the membrane portions, for example the thickness distribution having a rotational symmetry, can be designed to additionally correct chromatic aberration in addition to the correction of spherical aberrations.

While the foregoing is directed to embodiments, other and further embodiments may be devised without departing from the basic scope thereof, and the scope thereof is determined by the claims that follow.

1. A scanning charged particle beam apparatus, comprising:
a charged particle beam source configured for generating a primary charged particle beam;
an objective lens configured for forming a probe on a specimen, wherein the objective lens includes a decelerating electrostatic lens component;
a scanning deflection assembly configured for scanning the probe over a surface of the specimen; and
an aberration correction aperture, comprising:
an aperture body having a transparent aperture portion configured for having the primary charged particle beam pass through the transparent aperture portion; and
a membrane portion including a solid material, wherein the membrane portion is provided at the transparent aperture portion and wherein the membrane portion is configured for having the primary charged particle beam pass through the solid material, wherein the membrane portion has a varying thickness.

2. The scanning charged particle beam apparatus according to claim 1, wherein the membrane portion has a rotational symmetry around a center of the transparent aperture portion.

3. The scanning charged particle beam apparatus according to claim 2, wherein the membrane portion has varying thickness as a function of a radial position around the center.

4. The scanning charged particle beam apparatus according to claim 1, wherein the aberration correction aperture is a beam limiting aperture and the transparent aperture portion in the aperture body provides a portion of the primary charged particle beam, which is used for forming of the probe.

5. The scanning charged particle beam apparatus according to claim 4, wherein the aperture body further comprises:
a beam blocking portion around the transparent aperture portion configured to block charged particles.

6. The scanning charged particle beam apparatus according to claim 1, wherein the varying thickness has a local maximum at the center of the membrane portion and wherein the varying thickness has at least partially a radial increase.

7. The scanning charged particle beam apparatus according to claim 1, wherein the varying thickness is configured to introduce a phase shift within the primary charged particle beam.

8. The scanning charged particle beam apparatus according to claim 1, wherein the membrane portion is integrally formed with the aperture body.

9. The scanning charged particle beam apparatus according to claim 1, wherein the membrane portion is attached to the aperture body, optionally to a foil of the aperture body provided at the transparent aperture portion of the aperture body.

10. The scanning charged particle beam apparatus according to claim 1, wherein the solid material has a membrane opening within the transparent aperture portion.

11. The scanning charged particle beam apparatus according to claim 1, wherein the aperture body has at least a further transparent aperture portion, wherein the further transparent aperture portion is configured for having a further primary charged particle beam passing through the further transparent aperture portion;
wherein the aberration correction aperture further comprises:
a further membrane portion including a further solid material, wherein the further membrane portion is provided at the further transparent aperture portions, and wherein the further membrane portion is configured for having the further primary charged particle beam passing through the further solid material,
wherein the further membrane portion has a further varying thickness.

12. The scanning charged particle beam apparatus according to claim 11, wherein the varying thickness has a first thickness distribution different from a second thickness distribution of the further varying thickness.

13. The scanning charged particle beam apparatus according to claim 1, further comprising:
a spray aperture, which is positioned downstream along the primary charged particle beam of the aberration correction aperture, wherein the spray aperture is configured for blocking charged particles scattered from the aberration correction aperture.

14. The scanning charged particle beam apparatus according to claim 1, further comprising:
monochromator configured for reducing an energy width of the primary charged particle beam.

15. The scanning charged particle beam apparatus according to claim 1, wherein the scanning charged particle beam apparatus further comprises an electrode arrangement for accelerating the primary charged particle beam to a column energy of 10 keV or above, e.g. 30 keV or above.

16. The scanning charged particle beam apparatus according to claim 15, wherein the aberration correction aperture is configured to be biased to a potential corresponding to the column energy.

17. A scanning charged particle beam apparatus, comprising:
a charged particle beam source configured for generating a primary charged particle beam;
an objective lens configured for forming a probe on a specimen;
a scanning deflection assembly configured for scanning the probe over a surface of the specimen; and
an aberration correction aperture, comprising:
an aperture body having a transparent aperture portion configured for having the primary charged particle beam pass through the transparent aperture portion; and
a membrane portion including a solid material, wherein the membrane portion is provided at the transparent aperture portion and wherein the membrane portion is configured for having the primary charged particle beam pass through the solid material, wherein the membrane portion has a varying thickness,
wherein the aberration correction aperture is a beam limiting aperture and the transparent aperture portion in the aperture body provides a portion of the primary charged particle beam, which is used for forming of the probe.

18. A method of operating a scanning charged particle beam apparatus, comprising:
generating a primary charged particle beam;
correcting aberrations of the primary charged particle beam with an aberration correction aperture, wherein at least a portion of the primary charged particle beam passes through a membrane portion of the aberration correction aperture for introducing a phase shift within the primary charged particle beam; and
decelerating the primary charged particle beam by a factor of 5 or more before impingement on the specimen.

19. The method according to claim 18, further comprising:
focusing the primary charged particle beam on a specimen having a first spot size;
changing a demagnification of the charged particle beam apparatus;
switching between the membrane portion of the aberration correction aperture having a first thickness distribution and a further membrane portion having a second thickness distribution different from the first thickness distribution; and
focusing the primary charged particle beam on the specimen having a second spot size different from the first spot size.

20. The method according to claim 18, further comprising:
delimiting an aperture angle of the primary charged particle beam with an aberration correction aperture.
